(19) United States
(12) Patent Application Publication
(10) Pub. No.: US 2013/0236634 A1
(43) Pub. Date: Sep. 12, 2013

(54) CHEMICAL VAPOR DEPOSITION APPARATUS AND METHOD OF DEPOSITING THIN FILM USING THE SAME

(71) Applicant: SAMSUNG ELECTRONICS CO., LTD., Suwon-si (KR)

(72) Inventors: Sung Min CHOI, Anyang (KR); Dong Ju LEE, Suwon (KR); Heon Ho LEE, Seongnam (KR); Jang Mi KIM, Seoul (KR); Ok Hyun KIM, Busan (KR)

(73) Assignee: SAMSUNG ELECTRONICS CO., LTD., Suwon-si (KR)

(21) Appl. No.: 13/789,901

(22) Filed: Mar. 8, 2013

(30) Foreign Application Priority Data
Mar. 9, 2012 (KR) 10-2012-0024412

(51) Int. Cl. C23C 16/52

(52) U.S. Cl. CPC C23C 16/52
USPC 427/8; 118/708

(57) ABSTRACT

There is provided a chemical vapor deposition apparatus, including: a reaction chamber including a support part having a wafer placed thereon and a gas supply part supplying a process gas to a reactive space formed above the support part to allow a thin film to be grown on a surface of the wafer; a heat exchanger changing a temperature of the process gas, supplied to the reactive space through the gas supply part, to allow the process gas to be maintained at a set temperature: and a controller regulating a flow rate of the process gas, and detecting a temperature difference between a temperature of the process gas and the set temperature to thereby control the heat exchanger to supply the process gas to the reactive space while the process gas is maintained at a reference temperature set according to each stage.

### CROSS-REFERENCE TO RELATED APPLICATION

This application claims priority from Korean Patent Application No. 10-2012-0024412 filed on Mar. 9, 2012, in the Korean Intellectual Property Office, the disclosure of which is incorporated herein by reference in its entirety.

### BACKGROUND

1. Field

Apparatuses and methods consistent with exemplary embodiments relate to a chemical vapor deposition apparatus and a method of depositing a thin film using the same.

2. Description of the Related Art

Several kinds of thin film forming methods are used in order to grow a thin-film nitride semiconductor layer for a light emitting diode. Among them, chemical vapor deposition (CVD) methods are variously classified as atmospheric pressure CVD (APCVD), low-pressure CVD (LPCVD), metalorganic CVD (MOCVD), plasma-enhanced CVD (PECVD), and the like, depending on the kind of material used as a precursor, the pressure during a process, the manner in which energy necessary for reaction is transferred, and other characteristics. Even using the same CVD method, physical properties of deposited thin films may vary depending on the precursor supplying method, the type of reaction chamber, the constitution of an exhaust line, and the like.

In the case of a light emitting diode, it may be important to deposit a thin film on a wafer to have a uniform thickness, and an important factor that may affect uniform growth of the thin film may be whether or not the temperature of the precursor supplied during the thin film growing procedure is uniform.

However, the temperature of the precursor supplied to a reaction chamber is generally different, depending on type of, or flow rate of, the precursor, a temperature of a susceptor for heating a substrate, internal pressure of the reaction chamber, and the like. This phenomenon affects temperature gradients of an upper portion of a surface of the substrate, and thus, it may be difficult to obtain or stably maintain required growth conditions of the thin film.

### SUMMARY

One or more exemplary embodiments may provide a chemical vapor deposition apparatus and a method of depositing a thin film using the same, capable of growing a thin-film semiconductor layer under stable thin film growth conditions by accurately regulating a temperature of a process gas supplied to a reaction chamber.

According to an aspect of an exemplary embodiment, there is provided a chemical vapor deposition apparatus, including: a reaction chamber including a support part having a wafer placed thereon and a gas supply part supplying a process gas to a reactive space formed above the support part to allow a thin film to be grown on a surface of the wafer; a heat exchanger changing a temperature of the process gas, supplied to the reactive space through the gas supply part, to allow the process gas to be maintained at a set temperature, a controller regulating a flow rate of the process gas supplied according the growth stage of the thin film in the reaction chamber, and detecting a temperature difference between a temperature of the process gas induced from an outside and the set temperature to thereby control the heat exchanger to supply the process gas to the reactive space while the process gas is maintained at a reference temperature set according to each stage.

The controller may detect the temperature difference between the temperature of the process gas and the set temperature at each stage through previously input temperature information set according to each stage; calculate an amount of heat required for changing the temperature of the process gas by the detected temperature difference through previously input heat capacity information and process gas flow rate information, and control the heat exchanger to change the temperature of the process gas by the calculated amount of heat.

The controller may control an operation of the heat exchanger in advance before a growth stage of each thin film.

The controller may regulate the flow rate of the process gas at each stage through previously input process gas flow rate information provided according to each stage and time information used.

The chemical vapor deposition apparatus may further include a flow rate regulator regulating the flow rate of the process gas transferred according to each stage, to thereby transfer the process gas in a necessary amount according to each stage in which the thin film is grown.

According to an aspect of another exemplary embodiment, there is provided a method of depositing a thin film, the method including: supplying, by a gas supply part, a process gas induced from an outside to a reactive space in a reaction chamber; regulating, by a controller, a flow rate of the process gas supplied according to each stage in which the thin film is grown in the reaction chamber; controlling, by the controller, an operation of a heat exchanger to supply the process gas to the reactive space while the process gas is maintained at a reference temperature set according to each stage; and regulating, by the heat exchanger, a temperature of the process gas by changing a temperature of the process gas to allow the temperature of the process gas to reach the reference temperature.

The controller may control an operation of the heat exchanger by detecting a flow rate of the process gas changed according to each stage in which the thin film is grown and a temperature difference between the temperature of the process gas induced from an outside and the set reference temperature.

The controller may detect the temperature difference between the temperature of the process gas and the set temperature at each stage through previously input temperature information set according to each stage, calculate an amount of heat required for changing the temperature of the process gas by the detected temperature difference through previously input heat capacity information and process gas flow rate information, and control the heat exchanger to change the temperature of the process gas by the calculated amount of heat.

The controller may control an operation of the heat exchanger in advance before a growth stage of each thin film.

The controller may regulate the flow rate of the process gas at each stage through previously input process gas flow rate information provided according to each stage and time information used.

In the supplying of the process gas to the reaction chamber, the flow rate of the process gas transferred according to each stage may be regulated by a flow rate regulator controlled by the controller, to thereby transfer the process gas in a necessary amount according to each stage in which the thin film is grown.

The method may further include inputting flow rate information, time information, reference temperature information and heat capacity information, with respect to the process gas according to each stage, to the controller.

### BRIEF DESCRIPTION OF THE DRAWINGS

The above and/or other aspects, features, and advantages of will be more clearly understood from the following detailed description of exemplary embodiments taken in conjunction with the accompanying drawings, in which:

FIG. 1 is a cross-sectional diagram schematically illustrating a chemical vapor deposition apparatus according to an exemplary embodiment;

FIGS. 2A and 2B are views schematically illustrating a reaction chamber employable in the chemical vapor deposition apparatus of FIG. 1; and

FIG. 3 is a flow chart of a method of depositing a semiconductor layer according to an exemplary embodiment.

### DETAILED DESCRIPTION OF THE EMBODIMENTS

Hereinafter, exemplary embodiments will be described in detail with reference to the accompanying drawings.

However, the invention may be embodied in many different forms and should not be construed as being limited to the embodiments set forth herein.

The exemplary embodiments are provided so that those skilled in the art may more completely understand the inventive concept.

In the drawings, the shapes and dimensions of elements may be exaggerated for clarity, and the same reference numerals will be used throughout to designate the same or like components.

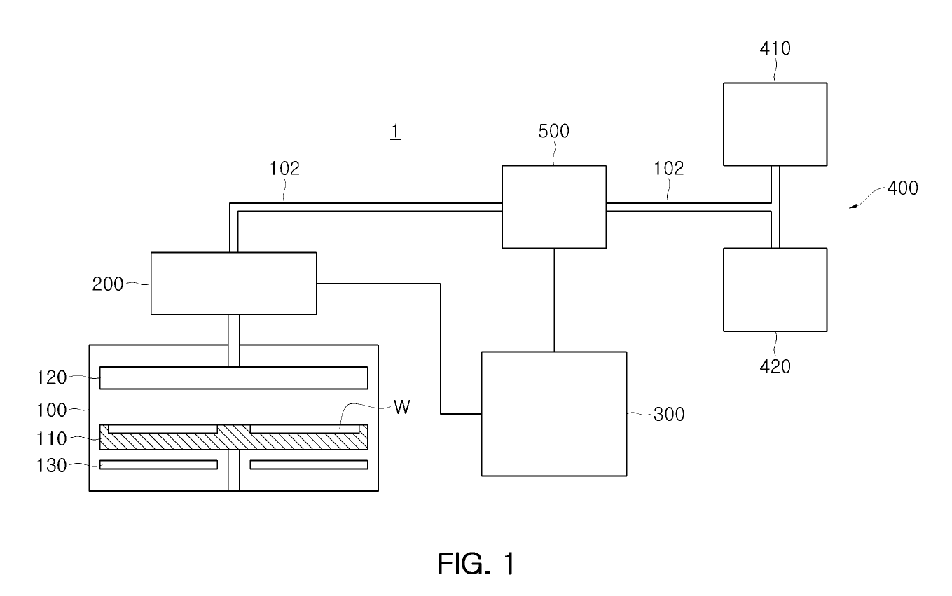

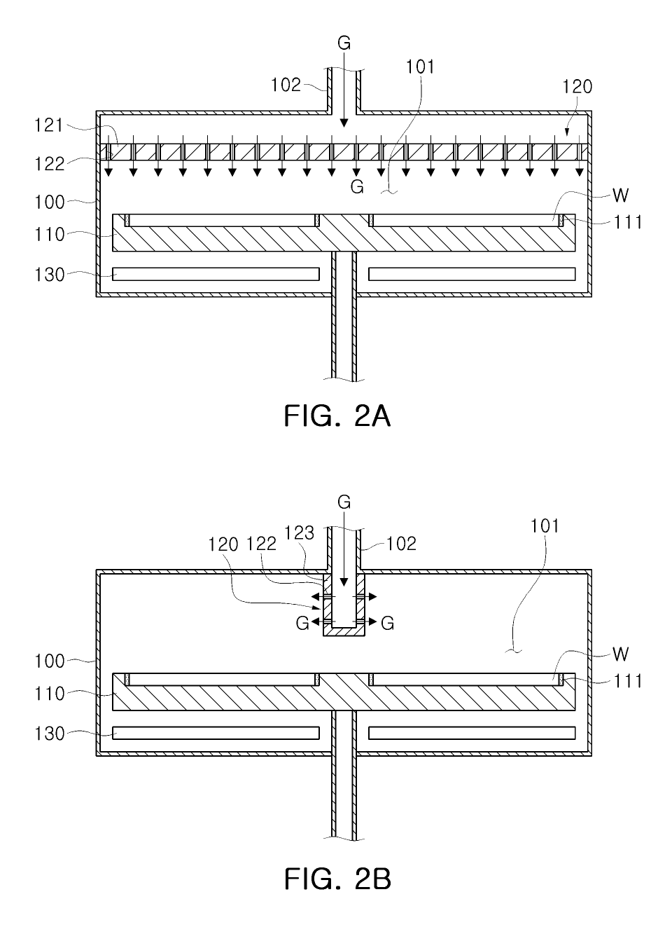

Referring to FIGS. 1 and 2, a chemical vapor deposition apparatus according to an exemplary embodiment will be described. FIG. 1 is a cross-sectional diagram schematically illustrating a chemical vapor deposition apparatus according to an exemplary embodiment, and FIGS. 2A and 2B are views schematically illustrating a reaction chamber employable in the chemical vapor deposition apparatus of FIG. 1.

As shown in FIG. 1, a chemical vapor deposition apparatus 1 may include a reaction chamber 100, a heat exchanger 200, a controller 300, a process gas storage room 400, and a flow rate regulator 500.

The reaction chamber 100 may be a closed type chamber having an inner space. The reaction chamber 100 may include a support part 110, having a wafer W placed thereon, and a gas supply part 120, supplying a process gas to a reactive space 101 formed above the support part 110 to allow a thin-film semiconductor layer to be grown on a surface of the wafer W. The reaction chamber 100 may be formed of a metal material having excellent wear resistance and corrosion resistance.

The support part 110 is a kind of a susceptor, and is disposed within the inside space of the reaction chamber 100. The support part 100 may have at least one pocket 111 recessed into an upper surface thereof, such that the wafer W, as a subject for deposition, can be placed in the pocket 111. The support part 110 may be formed of a material such as SiO2, SiC, Al2O3, AlN, ceramic, graphite, or the like, so that the support part 110 is not deformed due to the high temperatures within the reaction chamber 100.

A heating unit 130, heating the wafer W placed on the upper surface of the support part 110, may be provided below the support part 110. The heating unit 130 is a heat transferring member generating heat at the time of applying power, and may be disposed in a region corresponding to the pocket 111.

The gas supply part 120 receives the process gas G from outside the reaction chamber 100 and supplies the process gas G to the reactive space 101 in the chamber 100, so that a thin film is deposited and grown on a surface of the wafer W.

The process gas G may include a first process gas G1 and a second process gas G2, and may be supplied in a mixed state in which the first process gas G1 and the second process gas G2 are mixed together. As the first process gas G1, a reactive gas (or a source gas) such as, TMGa, TEGa, TMAl, TMIn, Cp2Mg, or the like, may be used. In addition, as the second process gas G2, a non-reactive gas (or a carrier gas), such as, H2, N2, NH3, or the like, may be used.

The thin film is a kind of a semiconductor layer, and a plurality of semiconductor layers are grown and laminated on the wafer W to form a light emitting laminate constituting a light emitting diode. The semiconductor layers may include an n-type semiconductor layer, an active layer, and a p-type semiconductor layer sequentially deposited on the wafer W.

The gas supply part 120 may include a jet plate 121 disposed in an inner upper portion of the reaction chamber 100 and facing the support part 110, and a plurality of jet nozzles 122 arranged in the jet plate 121, as shown in FIG. 2A. In addition, the process gas G may be jetted in a shower-head manner by the plurality of jet nozzles 122 facing the support part 110. Alternately, as shown in FIG. 2B, the gas supply part 120 may include a jet tube 123, extending toward a center portion of the support part 110, in which the pocket 111 is not provided, and a plurality of jet nozzles 122 arranged along the circumference of the jet tube 123. In this case, the process gas G is jetted in a radial manner through the plurality of jet nozzles 122, so that the process gas G forms a radial gas flow above the support part 110.

The gas supply part 120 may be connected with a process gas storage room 400 via an induction pipe 102 which extends outside of the reaction chamber 100. The process gas storage room 400 may include a first process gas storage room 410, in which the first process gas G1 is stored, and a second process gas storage room 420, in which the second process gas G2 is stored. Thereby, the first process gas G1 and the second process gas G2 respectively stored in the first and second gas storage rooms 410 and 420 may be transferred to the gas supply part 120 through the induction pipe 102, and may thereby be supplied to the reaction chamber 100.

The flow rate of the process gas G may be regulated by the flow rate regulator 500. The flow rate regulator 500 may regulate the flow rate of the process gas G according to each stage, so that the process gas G is transferred in a necessary amount according to each stage in which the thin film is grown. The flow rate regulator 500 may be connected to the controller 300, and thus, the operation of the flow rate regulator 500 may be controlled. The controller 300 will be described later.

The heat exchanger 200 may heat or cool the process gas G transferred through the induction tube 102, so that the process gas G supplied to the reactive space 101 in the reaction chamber 100 may be maintained at a predetermined temperature. The heat exchanger 200 may include a cooler and a heater, and operations of the heat exchanger 200 may be controlled by the controller 300, to thereby selectively heat or cool the process gas G.

The controller 300 may control the flow rate regulator 500 so that the flow rate of the process gas G supplied according to each stage in which the thin film is grown in the reaction chamber 100, and control the operation of the heat exchanger 200 so that the process gas G is maintained at a temperature set according to each stage when being supplied.

Specifically, the controller 300 may regulate the flow rate of the process gas G through “process gas flow rate information G supplied according to each stage” and “time information used according to each stage”. For example, in a case in which the process gas G is used in an amount of 90 L and the time the gas is used for is 30 minutes, while growing the n-type semiconductor layer as a first thin film, flow rate information of 90 L and time information of 30 minutes are input to the controller 300. Further, in a case in which the process gas G is used in an amount of 150 L and the time the gas is used for is 120 minutes, in growing the active layer as a second film, flow rate information of 150 L and time information of 120 minutes are input to the controller 300.

Through this information, the controller 300 may control the flow rate regulator 500 to supply 90 L of the process gas G for 30 minutes, to thereby grow the n-type semiconductor layer. In addition, after the growth process of the first thin film is completed, the controller 300 may calculate a difference value in flow rate which is varied in order to grow the second thin film, the difference value being 60 L, and may control the flow rate regulator 500 to further supply the flow rate for growing the second film based on the calculated difference value, so that the process gas G is then supplied in a set flow rate, that is, 150 L, for 120 minutes, and thus, the active layer may be grown on the n-type semiconductor layer.

In the present embodiment, it is described that 90 L and 150 L of the process gas G and 30 minutes and 120 minutes of time are respectively used in order to grow the n-type semiconductor layer and the active layer. However, these quantities and times are merely exemplary and not intended to limit the inventive concept. The amount of process gas G used and the time during which the gas is used may be variously changed in consideration of the size of the reaction chamber 100, and/or other considerations, and may be determined by applying experimental data depending on the size of the reaction chamber 100.

Meanwhile, the controller 300 may control the heat exchanger 200 using “temperature information set according to each stage” input in order to maintain the temperature of the process gas G supplied according to each stage when being supplied, and thus, the temperature of the process gas G may be regulated. Specifically, the controller 300 compares a temperature of the process gas G received from the outside and the set temperature to thereby determine the type of operation of the heat exchanger 200, and detects a temperature difference therebetween. Then, the controller 300 calculates an amount of heat required for raising or lowering the temperature of the process gas G so as to correspond to the detected temperature difference, using the input “heat capacity information” of the process gas G and “flow rate information according to each stage”. Then, the operation of the heat exchanger 200 is controlled such that the heat is added to or removed from the process gas G by the calculated amount of heat. Here, the type of operation of the heat exchanger 200 indicates an operation of heating or cooling the process gas G. That is, when the set temperature, that is, the reference temperature, is higher than the temperature of the process gas G received from the outside, the controller 300 controls the heat exchanger 200 to heat the process gas G, and when the set temperature is lower than the temperature of the received process gas G, the controller 300 controls the heat exchanger 200 to cool the process gas G.

For example, in a case in which the temperature of the process gas G transferred from the process gas storage room 400 is 100° C., and the temperature set in order to grow the n-type semiconductor layer as the first thin film is 1050° C., set temperature information of 1050° C. is input to the controller 300. The controller 300 determines the type of operation of the heat exchanger 200 by comparing 100° C., the temperature of the process gas G, and 1050° C., the temperature previously set, and thus detects a temperature difference of 950° C. Then, the amount of heat necessary for raising the temperature of the process gas G by 950° C. is calculated using process gas (G) heat capacity information and flow rate information (90 L in the case of the above-described example) of the process gas G used in order to grow the n-type semiconductor layer, which are previously input. Here, various values such as the heat capacity information for calculating amount of heat may be input depending on the kind of the process gas G. As for the composition of the process gas G generally used, the first process gas G1, a source gas, is 2 L/min or less, and the second process gas G2, a carrier gas, is 1-200 L/min, and the flow rate and temperature characteristics of the process gas G may be substantially determined by the second process gas G2. Therefore, the heat capacity information may be information regarding the second process gas G2. For example, molar heat capacity data of 29.124 J/molK for N₂, 28.836 J/molK for H₂, and 35.06 J/molK for NH₃ may be input as the heat capacity information, and the necessary amount of heat corresponding to the temperature difference may be calculated through these pieces of information and flow rate information. In addition, the operation of the heat exchanger 200 may be controlled so that heat is added to the process gas G by the calculated amount of heat, whereby the process gas G may be maintained at 1050° C., the set temperature, when being supplied.

According to this exemplary embodiment, an n-type semiconductor layer is grown at a temperature of 1050° C., but this is merely exemplary. In addition, it is described that heat is added to the process gas G in order to raise the temperature by 950° C., corresponding to the temperature difference. However, according to another exemplary embodiment, there may be a case in which it is necessary to lower the temperature, and the operation of the heat exchanger 200 may be controlled such that heat is removed from the process gas G by the calculated amount of heat.

The controller 300 may control the operation of the heat exchanger 200 before growing the respective semiconductor layers. In a related art, the flow rate or temperature of the process gas G supplied is regulated in real time, by detecting flow rate or temperature data of the process gas G, during the growth process of the thin film, using a sensor or like provided in the reaction chamber 100 or the gas supply part 120, and then comparing the detected data. In this case, since the temperature is raised (or lowered) or the flow rate is regulated while the growth process progresses. Accordingly, the thin film growth conditions are not uniformly maintained, and are thus changed, so that the quality of the grown thin film may be degraded or defects may occur therein.

In the present embodiment, the temperature and the flow rate of the process gas G are automatically regulated according to the stage of each thin film using the previously set temperature information and flow rate information, and particularly, the operation of the heat exchanger 200 is controlled a predetermined time before each stage of the thin films. For example, in a case in which it takes 30 minutes to grow the first thin film as described above, the second thin film is grown by controlling the operation of the heat exchanger 200 according to the information previously input in order to grow the second thin film, at least several minutes or several seconds before the lapse of 30 minutes, instead of operating the heat exchanger 200 directly after the lapse of 30 minutes. In this way, in the growth stage of the second thin film, the process gas G is supplied while the temperature of the process gas G is changed to the temperature previously set according to the corresponding stage. As such, the operation of the heat exchanger 200 is controlled before the growth stage of the thin film starts, and thus, the process gas G is supplied at the correct set temperature in each stage, so that the growth process may progress smoothly. Therefore, sensors need not be separately provided as in the related art, resulting in simplifying constituents and reducing costs. In addition, since the process gas G may be maintained and supplied at the set temperature in the growth stage of each thin film, the quality of the grown thin film may be improved.

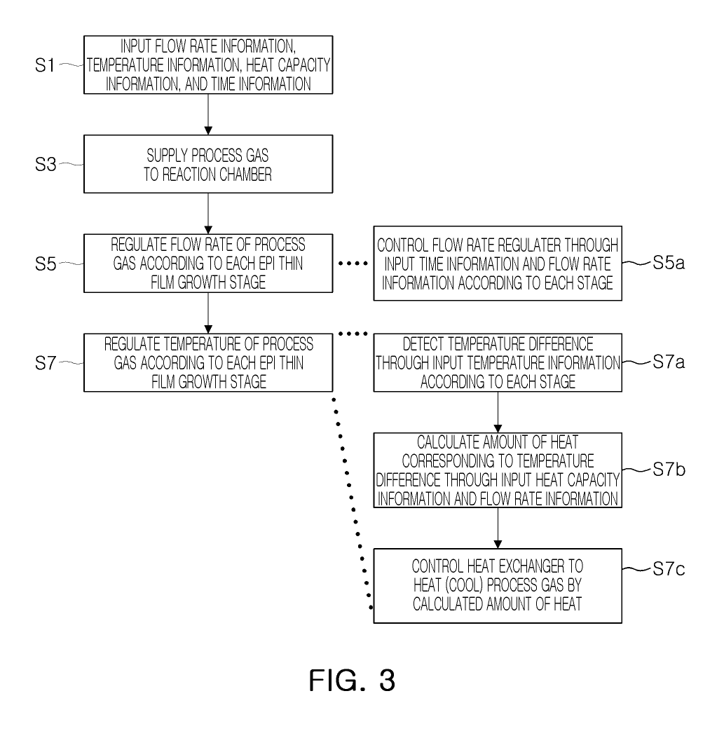

FIG. 3 schematically shows a flow chart of a method of depositing a thin film according to an exemplary embodiment.

As shown in FIG. 3, first flow rate information, time information, temperature information, heat capacity information, and the like, may be input to a controller with respect to a process gas for each stage in which a thin film is grown (S1).

Then, the process gas received from the outside may be supplied to a reactive space in a reaction chamber through a gas supply part (S3). This supplying of the process gas is performed such that the flow rate of the process gas is regulated by a controller according to each stage in which the thin film is grown in the reaction chamber (S5). Specifically, the flow rate of the process gas transferred is regulated according to time information such that the amount of the process gas needed according to each stage is transferred, using the previously input process gas flow rate information provided according to each stage and time information used according to each stage (S5a). For example, the controller may control the flow rate regulator to supply 90 L of the process gas for 30 minutes to thereby grow the n-type semiconductor layer as the first thin film, and then, may calculate a difference vale (60 L) of the flow rate changed in order to grow the active layer as the second thin film after the growth process of the first thin film is completed, and the flow rate regulator may be controlled to supply the flow rate of the process gas by the calculated difference value, so that the process gas is supplied in an amount of 150 L, the set flow rate, for 120 minutes. The flow rate of the process gas may be automatically regulated by the controller.

The temperature of the process gas transferred as such is regulated by the heat exchanger, so that the process gas is supplied to the reactive space while being maintained at a reference temperature set according to each stage (S7). Specifically, the controller compares a temperature of the process gas received from the outside and the set reference temperature, using the previously input temperature information according to each stage, and detects a temperature difference (S7a). Then, the controller calculates the amount of heat required for raising or lowering the temperature of the process gas by the detected temperature difference, using the previously input “heat capacity information” of the process gas and “flow rate information according to each stage” (S7b). Then, the operation of the heat exchanger is controlled so that heat is added to or removed from the process gas by the calculated amount of heat (S7c). In this way, the process gas may be maintained at the temperature set according to each stage when being supplied, and thus, the thin film growth conditions may be stably maintained.

As set forth above, according to one or more exemplary embodiments, there are provided a chemical vapor deposition apparatus and a method of depositing a thin film using the same, capable of forming a thin film under stable semiconductor layer growth conditions, by accurately regulating the temperature of the process gas supplied to the reaction chamber.

The effects of the present inventive concept are not limited to the above-described effects, and those skilled in the art will understand other technical effects that are not mentioned, from the descriptions above.

While exemplary embodiments have been shown and described herein, it will be apparent to those of skill in the art that modifications and variations can be made without departing from the spirit and scope of the inventive concept as defined by the appended claims.

What is claimed is:

1. A chemical vapor deposition apparatus, comprising:
a reaction chamber comprising a gas supply part which supplies a process gas into a reactive space of the reaction chamber;
a heat exchanger which receives the process gas, changes a temperatures of the process gas, and supplies the process gas to the gas supply part, wherein the heat exchanger heats; and
a controller which regulates a flow rate of the process gas supplied to the gas supply part based on a growth stage of a thin film within the reaction chamber, determines a temperature difference between a temperature of the process gas received by the heat exchanger and a set temperature, and controls the heat exchanger to change the temperature of the process gas, such that the process gas supplied to the gas supply part is maintained at the set temperature.

2. The chemical vapor deposition apparatus of claim 1, wherein the controller determines the temperature difference between the temperature of the process gas received by the heat exchanger and the set temperature based on temperature information which is input to the controller and which is set according to each growth stage of the thin film, wherein the controller calculates an amount of heat required to change the temperature of the process gas by the determined temperature difference using heat capacity information and process gas flow rate information which are input to the controller, and wherein the controller controls the heat exchanger to change the temperature of the process gas by the calculated amount of heat.

3. The chemical vapor deposition apparatus of claim 1, wherein, for each of a plurality of growth stages of the thin film, prior to the growth stage the controller controls the operation of the heat exchanger to supply the process gas at the set temperature according to the growth stage.

4. The chemical vapor deposition apparatus of claim 1, wherein the controller regulates the flow rate of the process gas using process gas flow rate information according to each stage and time information used which are input to the controller.

5. The chemical vapor deposition apparatus of claim 1, further comprising a flow rate regulator which regulates the flow rate of the process gas according to each growth stage of the thin film, such that the process gas is transferred to the reactive space in a necessary amount according to each growth stage of the thin film.

6. The chemical vapor deposition apparatus of claim 1, wherein the set temperature is determined according to the growth stage of the thin film.

7. A method of depositing a thin film, the method comprising: a heat exchanger receiving the process gas, changing a temperature of the process gas, and supplying the process gas to a gas supply part;
the gas supply part supplying the process gas to a reactive space within a reaction chamber;
a controller regulating a flow rate of the process gas supplied to the gas supply part based on a growth stage of a thin film in the reaction chamber;
the controller controlling an operation of the heat exchanger to change the temperature of the process gas to a set reference temperature according to the growth stage of the thin film.

8. The method of claim 6, wherein the controller controlling the operation of the heat exchanger comprises the controller detecting a change in the flow rate of the process gas according to the growth stage of the thin film, detecting a temperature difference between a temperature of the process gas received by the heat exchanger and the set reference temperature.

9. The method of claim 7, wherein the controller controlling the operation of the heat exchanger comprises the controller detecting a temperature difference between a temperature of the process gas received by the heat exchanger and the set reference temperature at each of a plurality of growth stages of the thin film using temperature information set according to each of the plurality of growth stages of the thin film and input to the controller, calculating an amount of heat required for changing the temperature of the process gas by the detected temperature difference using heat capacity information and gross gas flow rate information input to the controller, and controlling controls the heat exchanger to change the temperature of the process gas by the calculated amount of heat.

10. The method of claim 7, wherein the controller controlling the operation of the heat exchanger comprises the controller controlling the operation of the heat exchanger prior to each of a plurality of growth stages of the thin film.

11. The method of claim 7, wherein the controller regulating the flow rate of the process gas comprises the controller regulating the flow rate of the process gas at each of a plurality of growth stages of the thin film using process gas flow rate information for each of the plurality of growth stages and time information input into the controller.

12. The method of claim 6, wherein the controller regulating the low rate of the process gas supplied to the gas supply part comprises the controller regulating a flow rate regulator to transfer the process gas in an necessary amount according to each of a plurality of stages of the thin film.

13. The method of claim 6, further comprising inputting to the controller flow rate information, time information, reference temperature information and heat capacity information, with respect to the process gas according to each of a plurality of growth stages of the thin film.

14. A method of depositing a thin film, the method comprising:
a heat exchanger receiving process gas, changing a temperature of the process gas, and supplying the process gas to a gas supply part; and
the gas supply part supplying the process gas to a reactive space within a reaction chamber;
wherein the heat exchanger changing the temperature of the process gas and a flow rate of the process gas into the reactive space are controlled for each of a plurality of growth stages of a thin film, prior to each of the plurality of growth stages, such that, for each of the plurality of growth stages, a temperature of the process gas as supplied to the reactive space is constant.
